(19) United States
(12) Patent Application Publication
(10) Pub. No.: US 2020/0058429 A1
(43) Pub. Date: Feb. 20, 2020

(54) Fe-Co-Si ALLOY MAGNETIC THIN FILM

(71) Applicants: THE BOARD OF TRUSTEES OF THE UNIVERSITY OF ALABAMA, Tuscaloosa, AL (US); TDK CORPORATION, Tokyo (JP)

(72) Inventors: Takao Suzuki, Tuscaloosa, AL (US); Tim Mewes, Northport, AL (US); Gary Mankey, Tuscaloosa, AL (US); Claudia Mewes, Northport, AL (US); Kyotaro Abe, Tokyo (JP); Isao Kanada, Tokyo (JP); Yusuke Ariake, Tokyo (JP)

(21) Appl. No.: 16/545,517

(22) Filed: Aug. 20, 2019

Related U.S. Application Data
(60) Provisional application No. 62/719,886, filed on Aug. 20, 2018.

(51) Int. Cl. H01F 10/16; C30B 29/16; C30B 23/02; C30B 29/52; C23C 14/18; C22C 38/10; C22C 38/02

(52) U.S. Cl. CPC H01F 10/16; C30B 29/16; C30B 23/025; H01F 10/28; C23C 14/18; C22C 38/10; C22C 38/02; C30B 29/52

(57) ABSTRACT

An Fe—Co—Si alloy magnetic thin film contains, in terms of atomic ratio, 20% to 25% Co and greater than 0% to 20% Si. The Fe—Co—Si alloy magnetic thin film primarily has a body-centered cubic crystal structure. Among three <100> directions of the crystal structure, one of the three <100> directions is perpendicular to a substrate surface and the other two <100> directions are parallel to the substrate surface. The Fe—Co—Si alloy magnetic thin film deposited onto MgO (100) has suitable magnetic properties, that is, a high magnetization of 1100 to 1725 emu/cc, a coercive force of less than 95 Oe, and an effective damping parameter of less than 0.001.

### FIELD

The present disclosure relates to a soft magnetic material used in a high-frequency range that covers the gigahertz range and specifically to an iron (Fe)-cobalt (Co)-silicon (Si)-based magnetic thin film having a large magnetization, a low effective damping parameter, and a small coercive force.

### BACKGROUND

With increases in capacity and speed provided by communication technologies, magnetic materials used for producing electronic components, such as inductors, low-pass filters, and bandpass filters, are required to have a high magnetic permeability and a low magnetic loss even in a high-frequency band including the gigahertz band.

Magnetic losses in soft magnetic materials are typically caused by, for example, hysteresis loss, eddy current loss, and residual loss. The term “residual loss” refers to magnetic losses other than hysteresis loss or eddy current loss.

Hysteresis loss is proportional to the area of a magnetic hysteresis loop. Thus, reducing the coercive force reduces the area of a magnetic hysteresis loop and thereby reduces the hysteresis loss.

It is known that eddy current loss can be effectively reduced by increasing the electric resistance of a magnetic material and, in the case where a thin film is to be magnetized in an in-plane direction, by reducing the thickness of the thin film.

An example of residual loss is a magnetic loss caused by domain-wall resonance, resonance caused by rotation magnetization (i.e., ferromagnetic resonance), or the like. In order to limit domain-wall resonance, it is effective to form a structure that does not allow the formation of the domain walls by, for example, reducing the size of crystals of a magnetic material to a critical single-domain grain size or less. The critical single-domain grain size of isotropic iron crystals is about 28 nm.

The magnetic loss resulting from resonance caused by rotation magnetization can be reduced by narrowing the resonance linewidth even at a high frequency considerably close to the resonance frequency. That is, narrowing the resonance linewidth enables a reduction in magnetic loss in a wider frequency band. It is considered that the resonance linewidth of a magnetic material can be effectively narrowed by reducing inhomogeneity in the composition and disorder in crystallographic orientation of the magnetic material and minimizing the amount of defects and impurities contained in the surface and inside of the magnetic material.

The resonance linewidth can be measured by ferromagnetic resonance (FMR). The relationship between the resonance frequency fr and the resonance linewidth ΔH can be represented by expression (1) below.

ΔH=ΔH₀+4π/(√3γ)·α_{eff}·fr (1)

where ΔH₀ represents a linewidth at a frequency of 0 Hz, γ represents a gyromagnetic ratio, and α_{eff} represents an effective damping parameter. The smaller the parameters α_{eff} and ΔH₀, the smaller the resonance linewidth and the higher the frequency at which the magnetic loss can be reduced. The above parameters are not intrinsic physical properties and are parameters dependent on extrinsic factors, such as crystallographic orientation and microstructure.

In “Relaxation in epitaxial Fe films measured by ferromagnetic resonance”, Bijoy K, R. E. Camley, and Z. Celinski, ferromagnetic resonance of an iron thin film prepared by molecular beam epitaxy is measured. The smaller the thickness of the thin film, the larger the resonance linewidth due to extrinsic factors, such as surface roughness, accordingly. The intrinsic damping parameter of the material which is determined by eliminating the influences of the extrinsic factors is reportedly small, that is, 0.003 with respect to the magnetic field linewidth and 0.0043 with respect to the frequency linewidth.

The influential extrinsic factors are the surface roughness of the material, strain and defects contained in the material, and the crystallographic orientation of the material. It is important to control these extrinsic factors. In particular, heating the substrate is effective to remove a strain in the material and control the crystallographic orientation of the material.

It is also widely known that increasing magnetization is effective to enhance magnetic permeability.

### SUMMARY

The present disclosure provides a magnetic material having a large magnetization, a low effective damping parameter, and a small coercive force which is suitable as a material for high-frequency electronic components.

An Fe—Co—Si alloy magnetic thin film according to an embodiment of the present disclosure contains, in terms of atomic ratio, 20% to 25% Co and greater than 0% to 20% Si. The Fe—Co—Si alloy magnetic thin film primarily has a body-centered cubic crystal structure. Among three <100> directions of the crystal structure, one of the three <100> directions is perpendicular to a substrate surface and the other two <100> directions are parallel to the substrate surface.

### DETAILED DESCRIPTION

The present disclosure is described below in detail. It should be understood that the scope of the present disclosure is not limited by the following example of implementation of the present disclosure (hereinafter, such examples are referred to as “embodiment”). The structural features of the present disclosure are not limited by the embodiment described below and features easily perceivable by a person skilled in the art, features that are substantially identical, and features that are equivalent are all included within the scope of the present disclosure.

An Fe—Co—Si alloy magnetic thin film according to an embodiment of the present disclosure contains, in terms of atomic ratio, 20% to 25% Co. For example, the Fe—Co—Si alloy magnetic thin film can contain, in terms of atomic ratio, 20%, 20.5%, 21%, 21.5%, 22%, 22.5%, 23%, 23.5%, 24%, 24.5%, or 25% Co. The magnetization of the Fe—Co—Si alloy magnetic thin film has a local maximum when the Co content in the magnetic thin film is 20% to 35%. The effective damping parameter of the Fe—Co—Si alloy magnetic thin film has a local minimum when the Co content in the magnetic thin film is 20% to 25%. Thus, the Fe—Co—Si alloy magnetic thin film has a suitable magnetization and a suitable effective damping parameter when the Co content in the magnetic thin film is 20% to 25%.

The Fe—Co—Si alloy magnetic thin film according to the embodiment contains, in terms of atomic ratio, greater than 0% to 20% Si. For example, the Fe—Co—Si alloy magnetic thin film can contain, in terms of atomic ratio, 0.5%, 1%, 1.5%, 2%, 2.5%, 3%, 4%, 5%, 6%, 7%, 8%, 9%, 10%, 12%, 14%, 15%, 16%, 18%, 20%, from 0.5% to 20%, from 0.5% to 18%, from 0.5% to 15%, from 1% to 20%, from 2.5% to 20%, from 5% to 20%, from 2% to 18%, or from 5% to 15% Si. It is considered that, the higher the Si content, the smaller the magnetostriction and the smaller the effective damping parameter of the Fe—Co—Si alloy magnetic thin film. However, an excessively high Si content in the Fe—Co—Si alloy magnetic thin film can reduce the magnetization of the Fe—Co—Si alloy magnetic thin film. When the Si content in the Fe—Co—Si alloy magnetic thin film is 0% to 20%, the Fe—Co—Si alloy magnetic thin film has a small effective damping parameter and a large magnetization. The Fe—Co—Si alloy magnetic thin film according to the embodiment contains, in terms of atomic ratio, from 55% to 80% Fe, considering Co and Si content mentioned above. For example, the Fe—Co—Si alloy magnetic thin film can contain, in terms of atomic ratio, from 55% to 79.5%, from 55% to 75%, from 60% to 80%, from 60% to 75%, or from 55% to 65% Fe, considering Co and Si content mentioned above.

The Fe—Co—Si alloy magnetic thin film comprises a body-centered cubic crystal structure. In some embodiments, the Fe—Co—Si alloy magnetic thin film primarily has or consists essentially of a body-centered cubic crystal structure. One of the three <100> directions of the body-centered cubic crystal structure is perpendicular to a substrate surface and the other two <100> directions are parallel to the substrate surface. Since a disturbance in the motion of the magnetic moment which results from, for example, disorder in crystallographic orientation and defects increases the resonance linewidth, reducing the disorder in crystallographic orientation, the defects, and the like narrows the linewidth of magnetic resonance and reduces the magnetic loss that occurs at high frequencies.

### Method for Producing Magnetic Material

The magnetic material disclosed herein can be produced by the following method. First, target materials, that is, raw materials, are prepared. The target materials can be single-element targets each comprising Fe, Co, or Si. Alternatively, a target material having a composition adjusted such that the thin film has the desired composition can be used. Two or more alloy targets can be used in combination in order to produce a thin film having the desired composition. In another case, an alloy target can be used in combination with a single-element target. The alloy target can be any one of an Fe—Co—Si alloy target, an Fe—Co alloy target, an Fe—Si alloy target, and a Co—Si alloy target. It is desirable to reduce the oxygen content in the target material to a minimum level because oxygen reduces the saturation magnetization of the magnetic material and increases the coercive force of the magnetic material.

The substrate used for the deposition of the film can be comprised of any material such as a metal, glass, silicon, or a ceramic which is preferably not reactive with Fe, Co, Si, an Fe—Co—Si alloy, an Fe—Co alloy, an Fe—Si alloy, or a Co—Si alloy. The substrate is particularly preferably a single-crystal MgO substrate whose (100) plane serves as a surface of the substrate.

It is desirable to reduce the amount of impurity elements, such as oxygen, contained in a vacuum chamber included in the film deposition apparatus, in which sputtering is conducted, to a minimum level. Accordingly, the vacuum chamber is preferably evacuated to 10⁻⁵ Torr or less and is more preferably evacuated to 10⁻⁶ Torr or less.

Prior to film deposition, the target material is desirably subjected to sufficient preliminary sputtering in order to expose a clean surface of the target material. Accordingly, the film deposition apparatus desirably has a shielding mechanism disposed between the substrate and the target and configured to be operable in a vacuum state. Sputtering is preferably performed by magnetron sputtering. The atmosphere gas is Ar, which is unreactive with the magnetic material. The power source used for sputtering can be a DC or RF power source and selected appropriately depending on the target material used.

The target material and substrate disclosed herein can be used for film deposition. Examples of the film deposition method include co-sputtering in which plural targets are used simultaneously to deposit plural components at a time and a multilayer-film method in which plural targets are used one by one sequentially to form a multilayer film.

In a multilayer-film method, an appropriate combination of target materials necessary for producing a magnetic material having the desired composition is selected from Fe, Co, Si, an Fe—Co—Si alloy, an Fe—Co alloy, an Fe—Si alloy, and a Co—Si alloy. Layers formed using the respective targets are stacked on top of one another in a predetermined order repeatedly to form a multilayer body having a predetermined thickness. In the case where the substrate includes an oxide of an element having a high standard free energy of formation of an oxide, such as SiO₂ glass, a film that does not contain Si and is comprised of Fe, Co, or an Fe—Co alloy is preferably deposited first on the substrate because a Si film is likely to become oxidized. In the case where the substrate includes an oxide of an element that has a higher standard free energy of formation of an oxide than Fe, the reactivity of the oxide with samples needs to be confirmed before use.

The thickness of the Fe—Co—Si-based magnetic thin film can be adjusted as desired by changing film-deposition rate, film-deposition time, argon-atmosphere pressure, and, in the case where the film is formed by a multilayer-film method, the number of times film deposition is conducted. For example, the thickness of the Fe—Co—Si-based magnetic thin film can be adjusted over a range of from 4 nm to 100 nm, from 5 nm to 100 nm, from 5 nm to 85 nm, or from 10 nm to 75 nm. In order to adjust the thickness of the Fe—Co—Si-based magnetic thin film, the relationship between the deposition conditions and the thickness of the Fe—Co—Si-based magnetic thin film can be determined in advance. The thickness of the Fe—Co—Si-based magnetic thin film is commonly measured by contact profilometry, X-ray reflectometry, ellipsometry, quartz crystal microbalance, or the like.

In order to narrow the resonance linewidth by reducing disorder in crystallographic orientation, inhomogeneity in composition, strain, and defects, the substrate can be heated while the Fe—Co—Si-based magnetic thin film according to the embodiment is formed. Alternatively, the Fe—Co—Si-based magnetic thin film can be heated subsequent to the formation of the film. Heating of the substrate or the atmosphere during or after the formation of the film is desirably performed in an inert gas, such as argon, or in vacuum in order not to oxidize the sample.

A protective film comprised of Mo, W, Ru, Ta, or the like can be formed on top of the Fe—Co—Si alloy magnetic thin film according to the embodiment in order to prevent oxidation of the magnetic thin film.

The Fe—Co—Si alloy magnetic thin film according to the embodiment is described in further detail with reference to Examples below, which do not limit the scope of the present disclosure.

### EXAMPLES

### Preparation of Samples

The target materials used were Fe, Fe-34at % Co, and Si. The substrate used for film deposition was a single-crystal MgO substrate having a surface that was the (100) plane. Film deposition was performed by a multilayer-film method in which magnetron sputtering was used. The single-crystal MgO substrate was placed on a sample holder provided with a heater with which the temperature can be controlled. Four sputtering guns were used in film deposition. The above three targets and a Ru target for protective film were each placed in a specific one of the sputtering guns. The atmosphere for film deposition was an Ar gas (4×10⁻³ Torr). On and above the substrate, an Fe layer, an Fe-34at % Co layer, and an Si layer were deposited on top of one another in this order. The above process was considered to be one cycle. Films having various thicknesses were prepared by changing the number of the cycles N. The film-deposition rates of the Fe layer, the Fe-34at % Co layer, and the Si layer were set to 0.12, 0.15, and 0.027 nm/s, respectively. The compositions of the magnetic thin films were each controlled by adjusting the thicknesses of the above layers by changing the respective film-deposition times. Some of the magnetic thin films were prepared without heating the substrate, while the other magnetic thin films were prepared while the temperature of the substrate was set to 200° C. or 300° C. An Ru protective layer having a thickness of 5 nm was formed on each of the magnetic thin films immediately after the film had been formed.

### Structure and Property Evaluation

The thicknesses of the Fe—Co—Si alloy thin films were determined by X-ray reflectometry. The crystal structures of the Fe—Co—Si alloy thin films were determined by an electron diffraction analysis in which a TEM was used and by an X-ray diffraction analysis. An in-plane XRD pattern of each of the Fe—Co—Si alloy thin films was measured in order to determine the crystallographic orientation of the epitaxially grown film. The compositions of the samples were measured by X-ray photoelectron spectroscopy (XPS). The saturation magnetization and coercive force of each of the samples were determined with a vibrating sample magnetometer (VSM). The effective damping parameter of each of the samples was determined on the basis of FMR measured at 12 to 66 GHz and 0 to 16.5 kOe.

Table shows the structure and magnetic properties of each of Fe—Co—Si thin films prepared by changing the thickness of the thin film and the temperature at which the substrate was heated during film deposition.

TABLE

| | Fe | Co | Si | Ts | Thickness | | Mₛ | H_{c} |
|---|---|---|---|---|---|---|---|---|
| | [at %] | [at %] | [at %] | [° C.] | [nm] | α_{eff} | [emu/cc] | [Oe] |
| Example 1 | 68.2 | 22.7 | 9.1 | Ambient | 57 | 0.003 | 1433 | 95 |
| Example 2 | 62.5 | 20.8 | 16.7 | Ambient | 66 | 0.001 | 1104 | 44 |
| Example 3 | 71.4 | 23.8 | 4.8 | Ambient | 8 | 0.007 | 1725 | 4 |
| Example 4 | 71.4 | 23.8 | 4.8 | Ambient | 20 | 0.002 | 1707 | 27 |
| Example 5 | 71.4 | 23.8 | 4.8 | Ambient | 43 | 0.002 | 1608 | 71 |
| Example 6 | 71.4 | 23.8 | 4.8 | Ambient | 59 | 0.002 | 1528 | 62 |
| Example 7 | 71.4 | 23.8 | 4.8 | Ambient | 81 | | 1517 | 63 |
| Example 8 | 71.4 | 23.8 | 4.8 | 200 | 4 | 0.008 | 1465 | 6 |
| Example 9 | 71.4 | 23.8 | 4.8 | 200 | 16 | 0.003 | 1609 | 17 |
| Example 10 | 71.4 | 23.8 | 4.8 | 200 | 42 | 0.002 | 1509 | 13 |
| Example 11 | 71.4 | 23.8 | 4.8 | 200 | 60 | 0.002 | 1404 | 16 |
| Example 12 | 71.4 | 23.8 | 4.8 | 200 | 82 | 0.003 | 1329 | 7 |
| Example 13 | 71.4 | 23.8 | 4.8 | 300 | 6 | 0.008 | 1567 | 11 |

The results shown in Table confirm that the Fe—Co—Si thin films prepared in Examples had a low effective damping parameter of 0.008 or less, a high saturation magnetization of 1100 to 1725 emu/cc, and a low coercive force of 95 Oe or less.

The results of the in-plane X-ray diffraction analysis confirmed that four peaks corresponding to bcc(200) plane occurred at intervals of 90° when each of the samples prepared in Examples was rotated one revolution in the in-plane direction regardless of the composition, the thickness of the sample, or the temperature Ts of the substrate. It was also confirmed that four peaks corresponding to MgO(200) plane of the single-crystal substrate occurred at intervals of 90° and were out of phase with the peaks of the Fe—Co—Si thin film by 45° . This confirm that one of the three <100> directions of the bcc crystal structure of the Fe—Co—Si thin films was oriented in the direction of the thickness of the film and the other two <100> directions were oriented in the in-plane direction. The results of the measurement of crystallographic orientation prove that, in Examples, an Fe—Co—Si alloy film was epitaxially grown on the MgO substrate.

It is considered that the Fe—Co—Si alloy thin films prepared in Examples had a suitable effective damping parameter because the disorder in crystallographic orientation of the thin films was small. It is also considered that the Fe—Co—Si alloy thin films prepared in some of the Examples where the temperature of the substrate was set to 200° C. or 300° C. during film deposition had a low coercive force because the inhomogeneity in element distribution was reduced, which resulted in elimination of extrinsic factors resulting from the microstructure of the material, such as reductions in defects and strains.

The above results show that the Fe—Co—Si alloy magnetic thin film according to the embodiment has a crystallographic orientation such that the (100) plane is parallel to the substrate surface and the <100> direction is perpendicular to the substrate surface and suitable magnetic properties, that is, a magnetization of 1100 to 1725 emu/cc, a coercive force of 95 Oe or less, and an effective damping parameter of 0.008 or less.

The magnetic material according to the embodiment can have a large magnetization, a small coercive force, and a low effective damping parameter, and can be suitable for use in the gigahertz band.

What is claimed is:

1. An Fe—Co—Si alloy magnetic thin film comprising, in terms of atomic ratio:
20% to 25% Co; and
greater than 0% to 20% Si,
the Fe—Co—Si alloy magnetic thin film comprises a body-centered cubic crystal structure,
wherein, among three <100> directions of the crystal structure, one of the three <100> directions is perpendicular to a substrate surface and the other two <100> directions are parallel to the substrate surface.

2. The Fe—Co—Si alloy magnetic thin film of claim 1, wherein the Fe—Co—Si alloy magnetic thin film consists essentially of a body-centered cubic crystal structure.

3. The Fe—Co—Si alloy magnetic thin film of claim 1, wherein the Fe—Co—Si alloy thin film is grown on a MgO single crystal substrate with (100) surface.

4. The Fe—Co—Si alloy magnetic thin film of claim 2, wherein the Fe—Co—Si alloy thin film is grown on a MgO single crystal substrate with (100) surface.
